(19) United States
(12) Patent Application Publication
(10) Pub. No.: US 2024/0006290 A1
(43) Pub. Date: Jan. 4, 2024

(54) LTH AND SVLC HYBRID CORE ARCHITECTURE FOR LOWER COST COMPONENT EMBEDDING IN PACKAGE SUBSTRATE

(71) Applicant: Advanced Micro Devices, Inc., Santa Clara, CA (US)

(72) Inventors: Sriranga Sai Boyapati, Austin, TX (US); Deepak Vasant Kulkarni, Austin, TX (US); Rajasekaran Swaminathan, Austin, TX (US)

(21) Appl. No.: 17/854,907

(22) Filed: Jun. 30, 2022

(51) Int. Cl. H01L 23/498; H01L 23/64; H01L 21/48

(52) U.S. Cl. CPC H01L 23/49827; H01L 23/642; H01L 23/645; H01L 21/4857; H01L 2224/73204; H01L 24/73

(57) ABSTRACT

An apparatus and method for efficiently transferring information as signals through a silicon package substrate. A semiconductor fabrication process (or process) begins with a relatively thin package substrate core layer and uses lasers to create openings in the package substrate at locations of the signal routes. The use of each of the relatively thin core layer and the lasers allows for reduction in the pitch of the signal routes. The process creates signal routes in the openings using stacked vias from one side of the package substrate to an opposite side of the package substrate. Additionally, the process forms the package substrate with multiple embedded passive components with different thicknesses in different layers of the package substrate. The embedded passive components are used to improve signal integrity of the signal routes.

### BACKGROUND

### Description of the Relevant Art

There is a growing demand for semiconductor packages that provide communication between one or more integrated circuits in a chip package and external components on a motherboard located externally from the chip package. Electronic products associated with mobile computing, wearable electronics, and the Internet of Things (IoT) drive the demand for small packages that utilize vertical signal interconnections. Examples of the chip packages used in these products include ball grid arrays (BGAs), chip scale packages (CSPs), and System in Packages (SiPs).

The demand for SiPs and more signal interconnects between the integrated circuits and the printed circuit board (PCB) also increases the demand for semiconductor package substrates (or package substrates). The package substrate is a part of the chip package that provides mechanical base support as well as provides an electrical interface for the signal interconnects. Vertical through silicon vias (TSVs) are formed in the silicon package substrate that has connections to the printed circuit board using bump pads. Groups of TSVs forming through silicon buses are used as interconnects between a base die, one or more additional integrated circuits, and routing on a printed circuit board (PCB) such as a motherboard or a card.

When transferring information between a transmitter and a receiver, typically, electrical signals are sent on multiple, parallel metal traces. Transmitters send the electrical signals across the parallel metal traces. Receivers receive the electrical signals. The metal traces have transmission line effects such as distributed inductance, capacitance, and resistance throughout its length. For modern integrated circuits, the interconnect capacitance reduces signal integrity and signal transfer rate more so than gate capacitance of semiconductor devices. The interconnect capacitance per unit length includes both sidewall fringing capacitance and cross-coupling capacitance. For example, the electromagnetic fields for the metal traces conducting signals and the return current on the ground plane create electrical interference on neighboring metal traces and on adjacent devices.

Designers provide multiple signal integrity components within or nearby the metal signal routes to reduce the distortion caused by the many sources of noise (transmission line effects). These components typically include passive elements arranged in a particular manner to prevent the source of noise from affecting the shape and amplitude of the electrical signals being sent across the metal signal routes. Examples of the passive elements are resistors, inductors, and capacitors. Placing these passive elements on the side of the silicon package substrate where the integrated circuits are located does not allow the passive elements to be fully utilized for noise reduction. In addition, the passive elements consume area on the silicon package substrate, which reduces the density of signal routes.

In view of the above, efficient methods and systems for transferring information as signals through a silicon package substrate are desired.

### BRIEF DESCRIPTION OF THE DRAWINGS

FIG. 1 is a generalized block diagram of a package substrate that includes multiple embedded passive components with different thicknesses in different layers of the package substrate.

FIG. 2 is a generalized block diagram of a cross-section view of package substrate being formed with signal routes and embedded passive components.

FIG. 3 is another generalized block diagram of a cross-section view of package substrate being formed with signal routes and embedded passive components.

FIG. 4 is another generalized block diagram of a cross-section view of package substrate being formed with signal routes and embedded passive components.

FIG. 5 is another generalized block diagram of a cross-section view of package substrate being formed with signal routes and embedded passive components.

FIG. 6 is another generalized block diagram of a cross-section view of package substrate being formed with signal routes and embedded passive components.

FIG. 7 is another generalized block diagram of a cross-section view of package substrate being formed with signal routes and embedded passive components.

FIG. 8 is another generalized block diagram of a cross-section view of package substrate being formed with signal routes and embedded passive components.

FIG. 9 is a generalized block diagram of a semiconductor chip package.

FIG. 10 is a generalized block diagram of a method for forming a package substrate that includes multiple embedded passive components with different thicknesses in different layers of the package substrate.

FIG. 11 is a generalized block diagram of a method for forming a semiconductor chip package with a package substrate that includes multiple embedded passive components.

FIG. 12 is a generalized block diagram of a semiconductor chip package with a package substrate that includes multiple embedded passive components.

While the invention is susceptible to various modifications and alternative forms, specific implementations are shown by way of example in the drawings and are herein described in detail. It should be understood, however, that drawings and detailed description thereto are not intended to limit the invention to the particular form disclosed, but on the contrary, the invention is to cover all modifications, equivalents and alternatives falling within the scope of the present invention as defined by the appended claims.

### DETAILED DESCRIPTION

In the following description, numerous specific details are set forth to provide a thorough understanding of the present invention. However, one having ordinary skill in the art should recognize that the invention might be practiced without these specific details. In some instances, well-known circuits, structures, and techniques have not been shown in detail to avoid obscuring the present invention. Further, it will be appreciated that for simplicity and clarity of illustration, elements shown in the figures have not necessarily been drawn to scale. For example, the dimensions of some of the elements are exaggerated relative to other elements.

Apparatuses and methods efficiently transferring information as signals through a silicon package substrate are contemplated. A semiconductor fabrication process (or process) forms a package substrate with one or more signal routes using stacked vias from one side of the package substrate to an opposite side of the package substrate. Therefore, these one or more signal routes forego using a plated through-hole (PTH). These signal routes have a smaller pitch than signal routes that do use plated through-holes. The process forms the package substrate with multiple embedded passive components with different thicknesses in different layers of the package substrate. To do so, the process begins with a relatively thin package substrate core layer and uses lasers to create openings in the package substrate at locations of the signal routes. The use of each of the relatively thin core layer and the lasers allows for reduction in the pitch of the signal routes. In contrast, using a relatively thick package substrate core and mechanical drilling increases the pitch of the signal routes. The relatively large openings created by the mechanical drilling reduces the reliability of later forming multiple embedded passive components with different thicknesses in different layers of the package substrate.

Examples of the embedded passive components are a resistor, an inductor, and a capacitor. The embedded passive components are used to improve signal integrity on the signal routes transferring data within the package substrate. For example, the embedded passive components are placed in the layers of the package substrate in a particular manner that performs impedance matching to minimize signal reflections, reduces signal skew by closely matching the lengths of the signal routes, reduces crosstalk, minimizes overshoot and undershoot of the electrical signals, and reduces electromigration interference.

The process places a first side of the package substrate on multiple interconnects of a motherboard. The process places an integrated circuit on a second side different from the first side of the package substrate. The process completes the connections of the chip package, which can be one of a ball grid array (BGA) surface mount package, a chip scale package (CSP), or a System in Package (SiP). A potential, such as at least one power supply voltage, is applied to one or more nodes of the chip package in addition to components on the motherboard. When the package substrate receives data to transfer, the package substrate conveys the data from a first side of the package substrate that received the data to a second side opposite the first side of the package substrate. The multiple embedded passive components with different thicknesses in different layers of the package substrate increase signal integrity of the electrical signals being transferred.

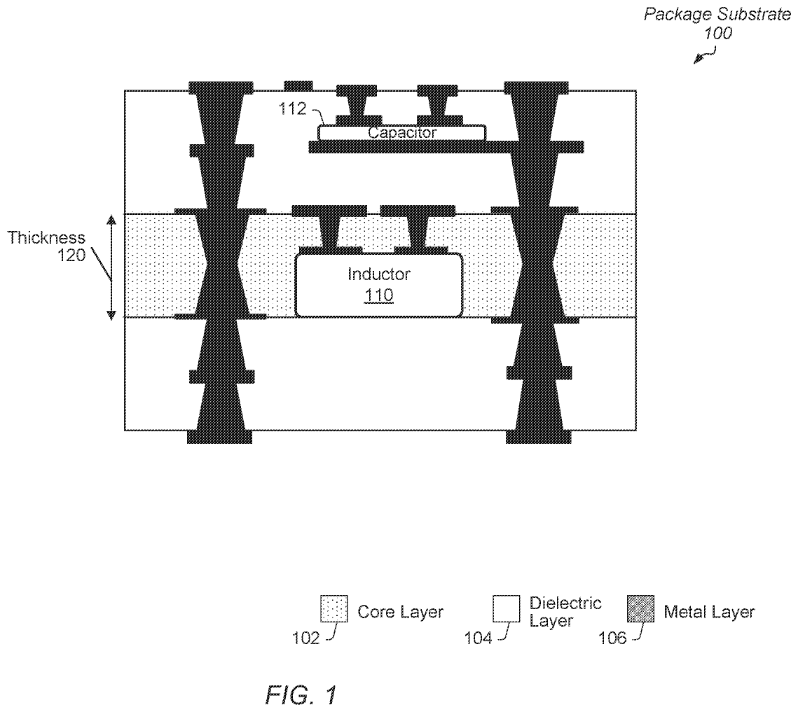

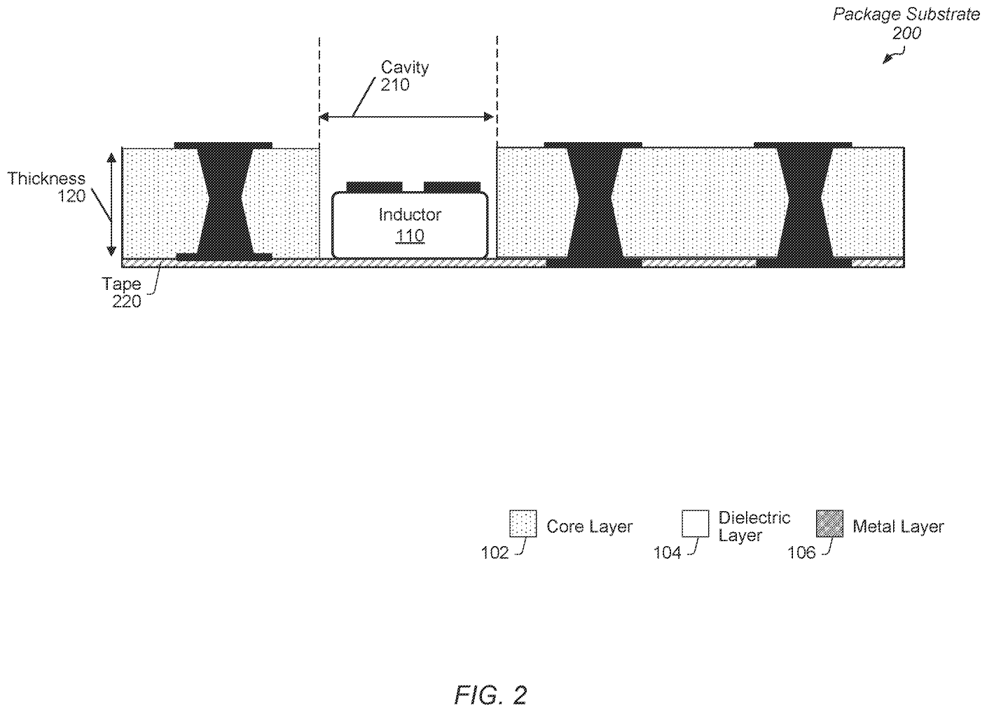

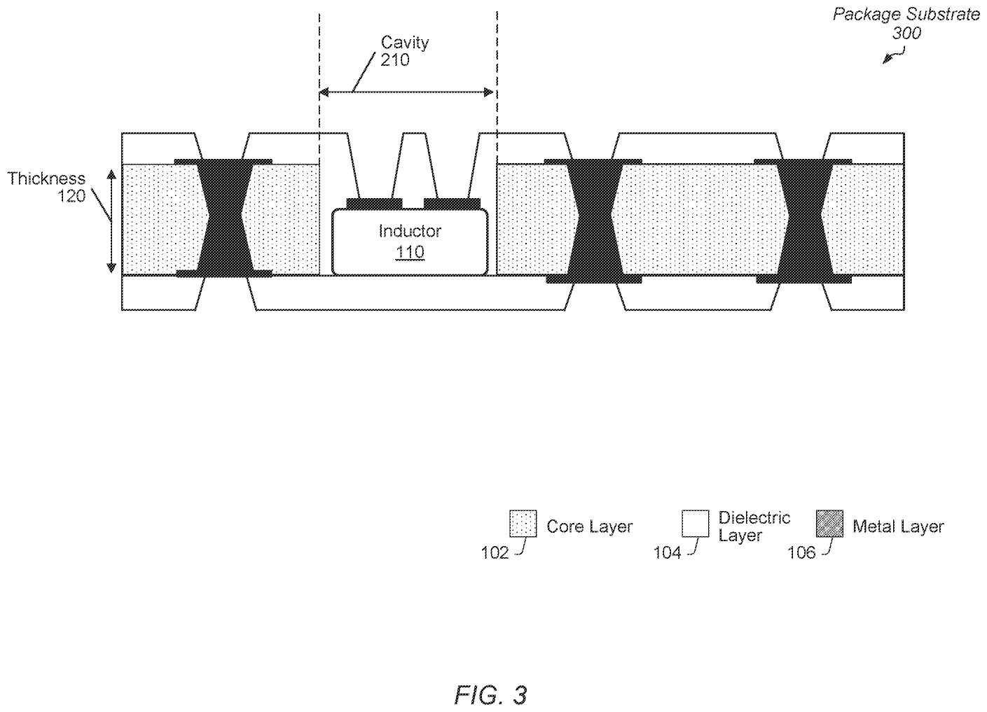

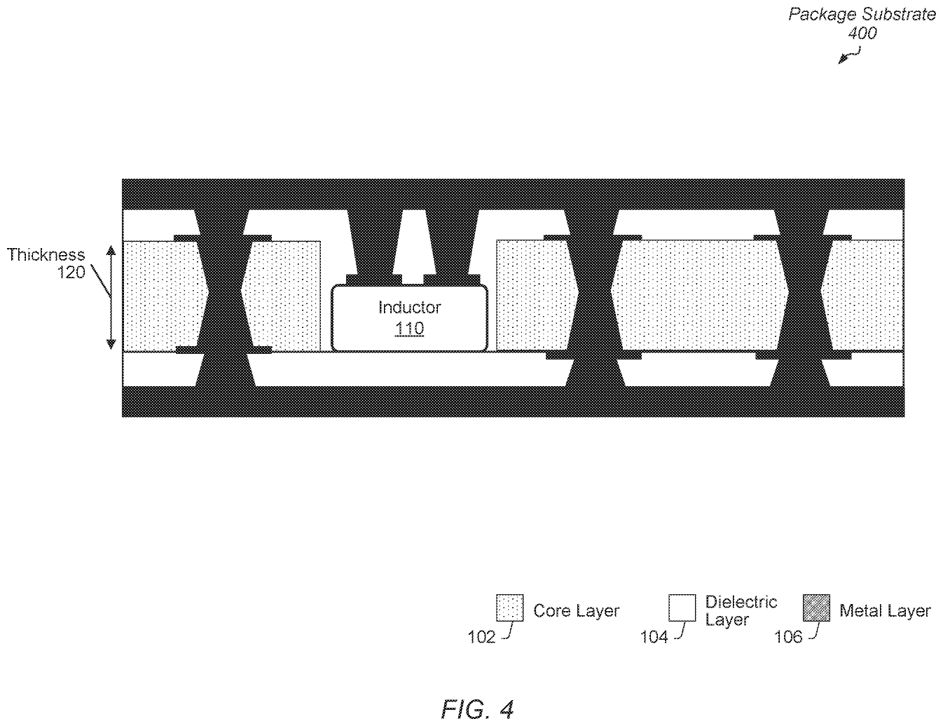

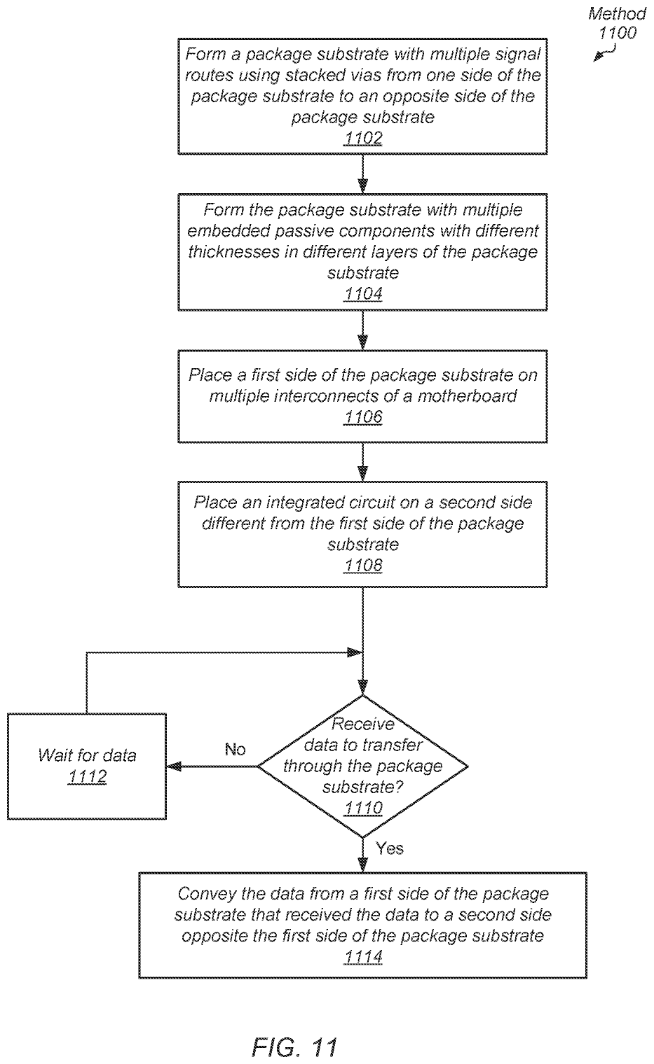

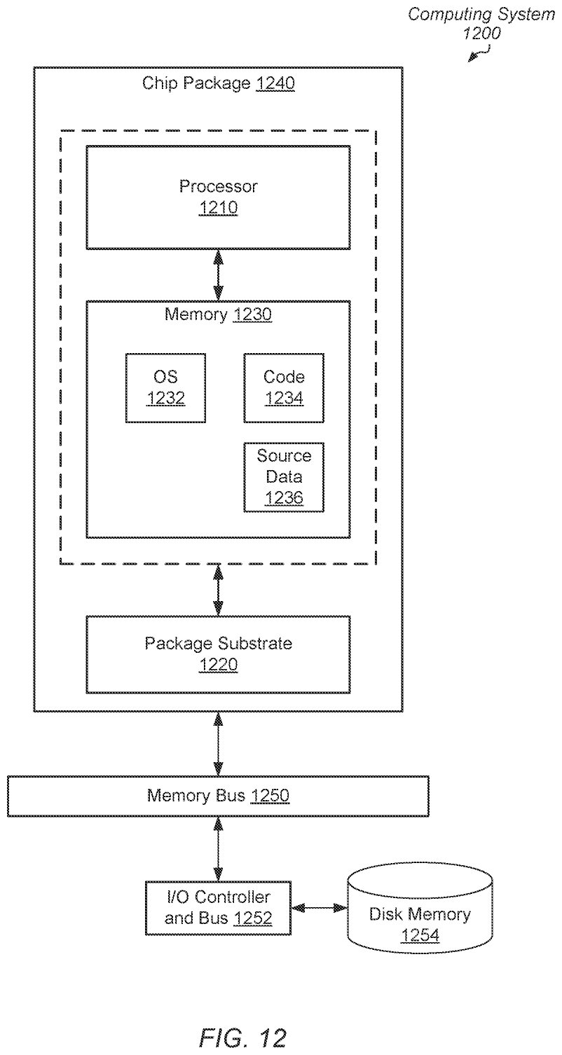

In the following description, multiple package substrates are shown in FIG. 1 that include multiple embedded passive components with different thicknesses in different layers of the package substrate. FIG. 2 illustrates a package substrate that relies on mechanical drilling for creating openings with a large pitch for plated through-holes. The relatively large and widely separated plated through-holes limit the number and type of embedded passive components that can be placed in the package substrate. FIG. 3 illustrates a semiconductor chip package. FIGS. 4-10 illustrate fabrication steps for creating the package substrate with multiple embedded passive components with different thicknesses in different layers of the package substrate. FIGS. 11-12 provide steps of methods to perform for creating the package substrate with multiple embedded passive components with different thicknesses in different layers of the package substrate. An example of a fabricated chip package, which includes the package substrate with multiple embedded passive components, placed in a computing system is shown in FIG. 13.

Referring to FIG. 1, a generalized block diagram is shown of a package substrate 100 with multiple embedded passive components located in multiple layers. As shown, the package substrate 100 includes a core layer 102 with a relatively small thickness 120. The thickness 120 of the core layer 102 is measured along the dimension of the package substrate 100 aligned with the direction of signal routes that transfer data as electrical signals through the package substrate 100. The signal routes use the metal layer 106 and stacked vias, rather than a plated through-hole (PTH). Although not shown for ease of illustration, it is possible and contemplated that one side, such as the bottom side in FIG. 1, of the package substrate 100 is placed on multiple interconnects of a motherboard. The other side of the package substrate 100 has one or more integrated circuits placed on another side, such as the top side in FIG. 1, of the package substrate 100. The core layer 102 includes a passive component, such as inductor 110, that has a thickness less than the thickness 120 of the core layer 102. The package substrate 100 also includes another passive component, such as capacitor 112, in a different layer than the inductor 110. Therefore, the package substrate 100 includes multiple embedded passive components (passive components 110 and 112) located in multiple layers of the package substrate 100.

The package substrate 100 also includes multiple layers of dielectric 104 with one or more of these layers having a different thickness and composition from other dielectric layers 104 of the package substrate 100. It is noted that, in various implementations, the thickness of the capacitor 112 is different from the thickness of the inductor 110. Therefore, the package substrate 100 includes multiple embedded passive components with different thicknesses.

In various implementations, the metal layer 106 includes copper or an alloy of other metals, such as aluminum, mixed with copper. Similar to the motherboard and other printed circuit boards, such as expansion cards, network cards, and video cards, the core layer 102 utilizes a glass-reinforced epoxy laminate material. This material provides relatively high mechanical strength while also providing electrical insulation between interconnects and semiconductor chips. One example of the glass-reinforced epoxy laminate material is the FR-4 (or FR4) glass epoxy. The core layer 102 includes one or more signal routes that are embedded in the FR-4 material and run through the FR-4 material. Another example is a glass bismaleimide triazine (BT) epoxy.

In various implementations, the dielectric layers 104 includes a variety of types of packaging dielectric layers. For example, a variety of types of a prepreg resin material is used. Prepreg is a reinforcing fabric that has been pre-impregnated with a resin, such as epoxy that already includes a curing agent. Therefore, the prepreg is ready to lay into a corresponding mold with more resin being added. A combination of heat and pressure is used to cure the laminate. Heat causes the prepreg material to soften, flow and surround the metal layers 106, bond multiple different layers together, and then fully cure. The dielectric layers 104 protect the metal layers 106 and the passive components, such as the inductor 110 and the capacitor 112, from physical, chemical, and electrical damage by insulating them.

It is noted that the core layer 102 is not mechanically drilled after the formations of the dielectric layers 104. Rather, to increase pitch density of the stacked vias used to create signal routes, the core layer 102 has openings created by lasers before the formations of the dielectric layers 104. In an implementation, the thickness 120 of the core layer 102 is 250 micrometers. The thicknesses of each of the inductor 110 and the capacitor 112 is less than the thickness of the core layer 102. To create openings in the core layer 102, lasers are used due to the relative thin core layer 102. In contrast, mechanical drilling is used to create openings in a core layer with a relatively high thickness of 1,000 micrometers (or 1 millimeter). The use of the relatively thin core layer 102 and the use of the lasers for creating openings for signal routes allows for the reduction in the pitch (increased pitch density) of the signal routes.

It is possible and contemplated that data can be transferred though the via stacks created in the package substrate 100 using the metal layer 106. The process creates signal routes in the openings created by lasers using stacked vias that include the metal layer 106. The stacked vias using the metal layer 106 create a signal route from one side of the package substrate 100 to an opposite side of the package substrate 100. Therefore, in various implementations, the package substrate 100 foregoes using plated through-holes (PTHs) for signal routes.

Examples of the embedded passive components placed in the package substrate 100 are a resistor, an inductor, and a capacitor. Although a single inductor 110 and a single capacitor 112 are shown, in other implementations, the package substrate 100 includes another number of passive components placed in different layers of the package substrate 100. The embedded passive components are used to improve signal integrity on the signal routes transferring data within the package substrate 100. For example, the embedded passive components, such as the inductor 110 and the capacitor 112, are placed in the layers of the package substrate 100 in a particular manner that performs impedance matching to minimize signal reflections, reduces signal skew by closely matching the lengths of the signal routes, reduces crosstalk, minimizes overshoot and undershoot of the electrical signals, and reduces electromigration interference.

When the package substrate 100 receives data to transfer, the package substrate 100 conveys the data from a first side of the package substrate 100, such as a top of the package substrate 100, that received the data to a second side opposite the first side of the package substrate 100. The multiple embedded passive components, such as at least inductor 110 and the capacitor 112, with different thicknesses in different layers of the package substrate 100 increase signal integrity of the electrical signals being transferred.

Turning now to FIG. 2, a generalized block diagram is shown of a cross-section view of a package substrate 200 being formed. Materials, layers, and components previously described are numbered identically. It is noted that the core layer 102 is not mechanically drilled after the formations of the dielectric layers 104. Rather, to increase pitch density of the stacked vias used to create signal routes, the core layer 102 has openings created by lasers before the formations of the dielectric layers 104. The core layer 102 has a relatively thin thickness 120 and lasers are used to form through-holes in locations for the stacked vias made of the metal layers 106. The laser-formed through-holes are electro-filled with copper or another metal mixture and patterned using existing standard processes.

The cavity 210 is formed for later embedding a passive component such as the inductor 110. A laminate temporary tape 220 is formed for component embedding. Afterward, the passive component, such as the inductor 110, is placed in the cavity 210. Although an inductor 110 is shown as being placed in the cavity 210, other types of passive components are placed in the cavity 210 in other implementations. It is noted that the width of the cavity 210, which is measured in a direction aligned with the pitch of the signal routes, is relatively small. The relatively small width of the cavity 210 causes the later cavity fill to be more manageable and increase yield. It is also noted that the thickness of the passive component, such as the inductor 110, is less than the thickness 120 of the core layer 102. After placement of the passive component in the cavity 210, a copper (Cu) adhesion promotion (AP) treatment step is performed.

FIGS. 3-8 illustrate subsequent processing steps for forming a package substrate with multiple embedded passive components located in multiple layers. For FIGS. 3-9, materials, layers, and components previously described are numbered identically. FIG. 3 illustrates a generalized block diagram of a package substrate 300 after a dielectric lamination step for filling the cavity 210, and the tape 220 has been removed. Another dielectric lamination step is performed followed by a curing step, and openings are created by lasers in the locations for the stacked vias. Afterward, a smear removal (de-smear) step is performed. FIG. 4 illustrates a generalized block diagram of a package substrate 400 after a copper seed layer deposition is performed using an electroless plating technique.

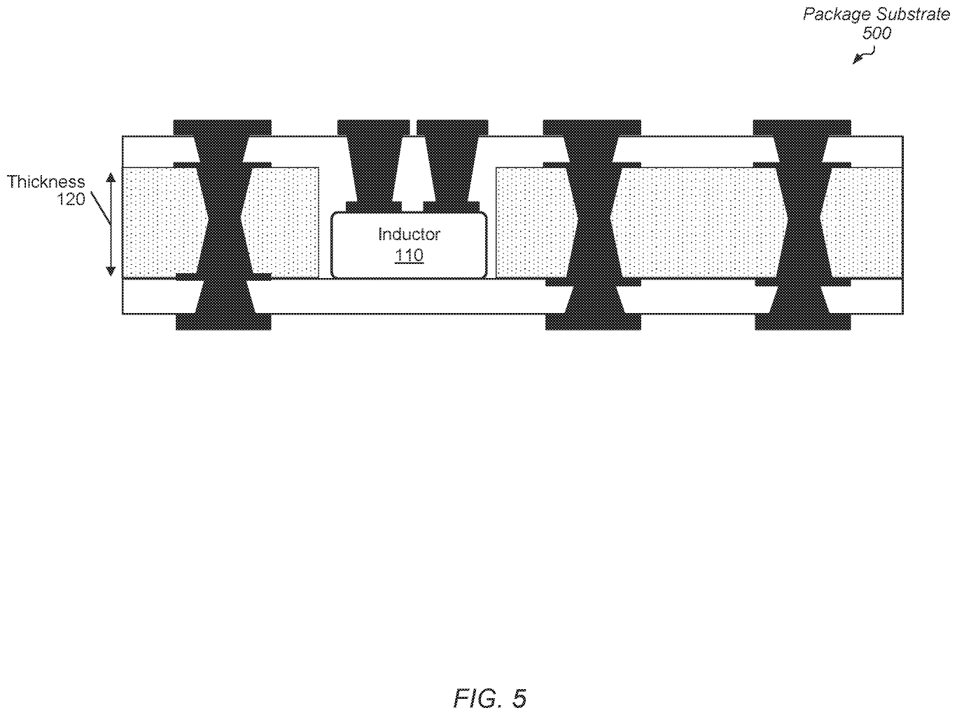

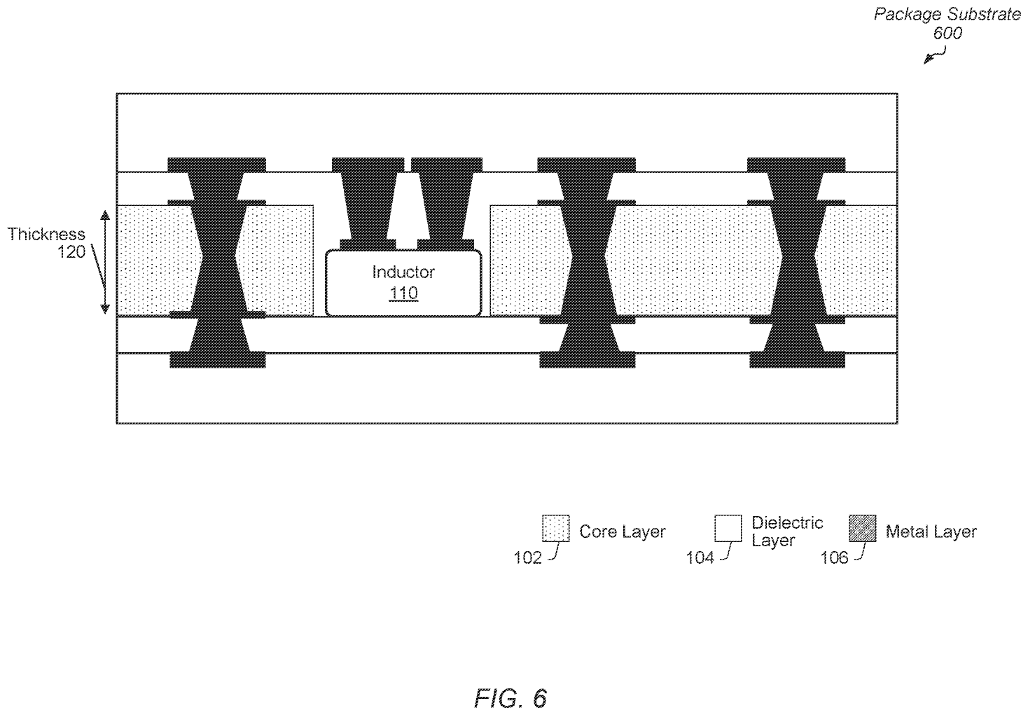

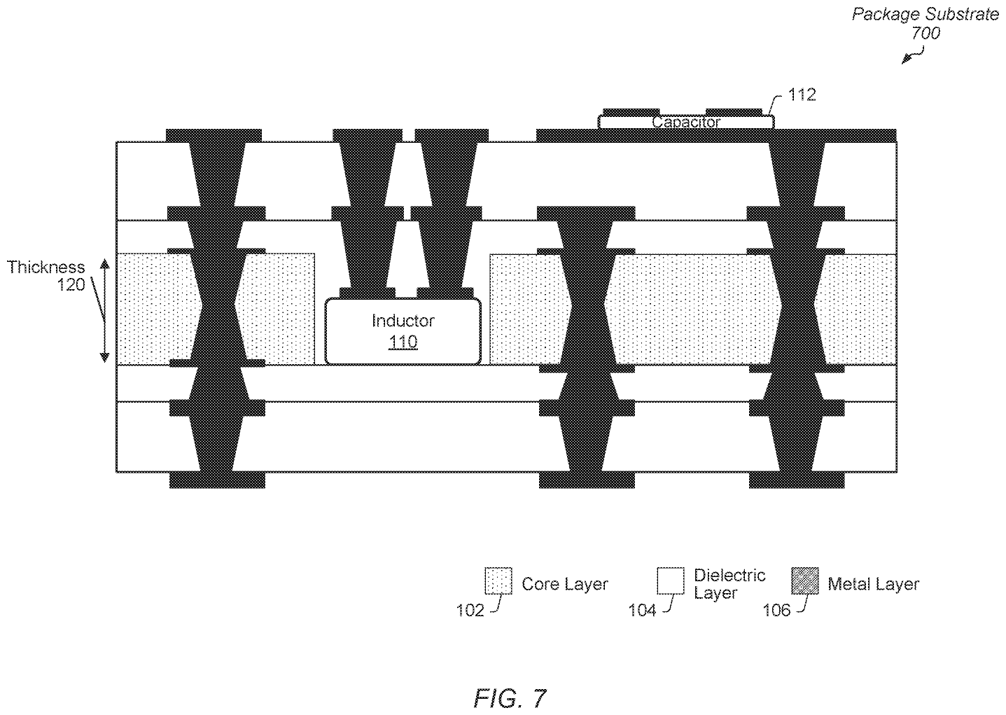

FIG. 5 illustrates a generalized block diagram of a package substrate 500 after a dry film photoresist (DFR) lamination process followed by an exposure step, a develop step, an etch step, and a strip step. FIG. 6 illustrates a package substrate 600 after a copper (Cu) adhesion promotion (AP) treatment step and dielectric lamination. FIG. 7 illustrates a generalized block diagram of a package substrate 700 after lasers create openings, a smear removal (de-smear) step, and after a copper seed layer deposition is performed using an electroless plating technique. Afterward, a DFR lamination process is performed followed by an exposure step, a develop step, an etch step, and a strip step. Afterward, a passive component, such as the capacitor 112, is placed.

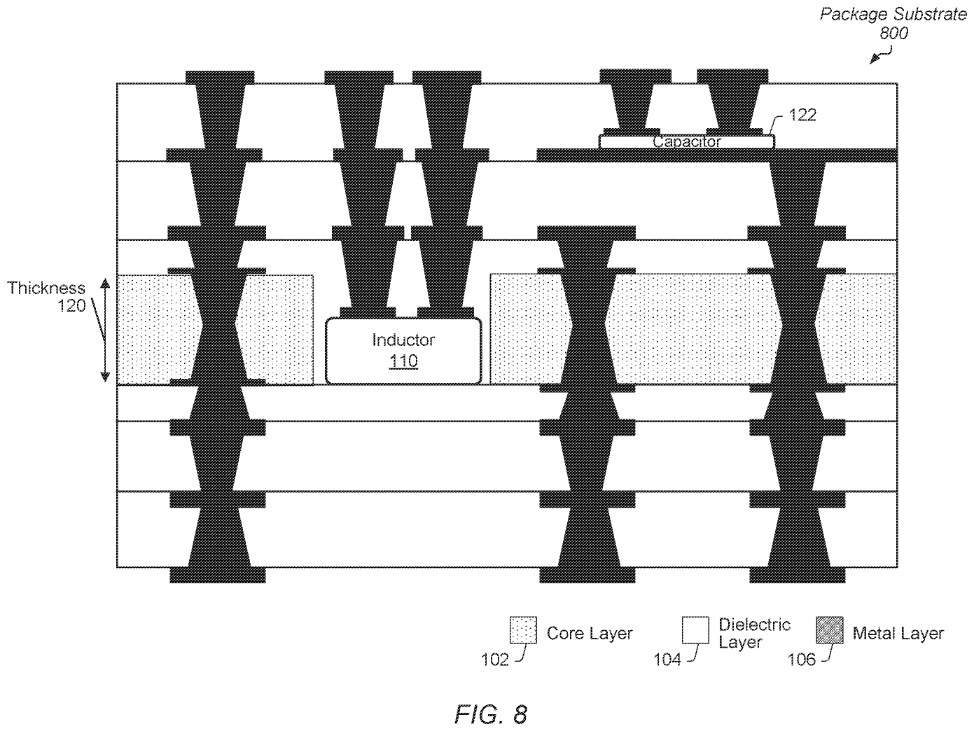

In various implementations, the capacitor 112 has a thickness different from the thickness of the inductor 110, and each of the thicknesses of the inductor 110 and the capacitor 112 is less than the thickness 120 of the core layer 102. Further, the capacitor 112 is placed in a different dielectric layer 104 than the core layer 102 where the inductor 110 is placed. FIG. 8 illustrates a generalized block diagram of a package substrate 800 after a copper (Cu) adhesion promotion (AP) treatment step and dielectric lamination.

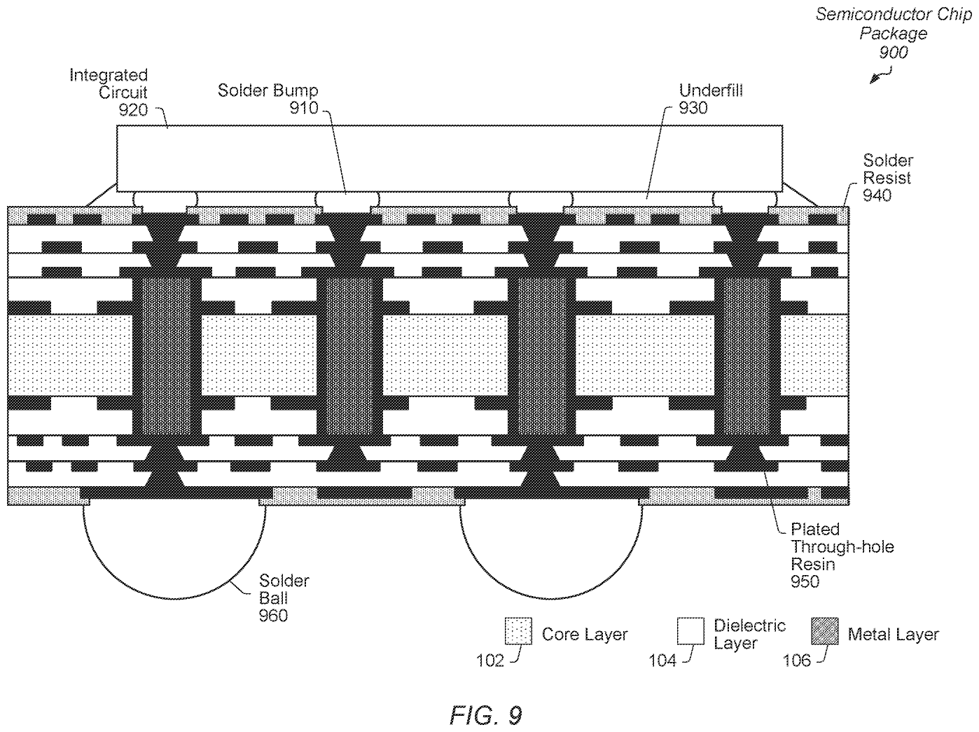

FIG. 9 illustrates a generalized block diagram of a semiconductor chip package 900. As shown, the semiconductor chip package 900 (or chip package 900) uses a variety of types of interconnects. One example are the controlled collapse chip connection (C4) interconnections 910, which are also referred to as flip-chip interconnection. Another example are the solder balls 960. The solder balls 960 provide a connection between the multiple layers of the package substrate and the motherboard (not shown). The solder resist 940 is an insulating ink that covers the surface of printed wiring boards and protects the circuit pattern. The underfill 930 is a composite material made up of an epoxy polymer that is used to compensate for thermal expansion of materials between the integrated circuit (IC) 920 and the package substrate. The integrated circuit 920 can be one of a variety of types of an integrated circuit. It is noted that the package substrate that is shown uses plated through-holes (PTHs) with a corresponding resin 950, and accordingly, consumes more area and has a less pitch density for signal routes than the signal routes illustrated in FIGS. 1-8. Replacing the approach that creates PTHs with the approaches described earlier regarding FIGS. 1-8 provides a thinner core layer 102 and a higher pitch density for signal routes and allows the placement of multiple embedded passive components located in multiple layers of the package substrate. Further, these embedded passive components have varying thicknesses compared to one another and the thicknesses are less than the thickness of the core layer 102.

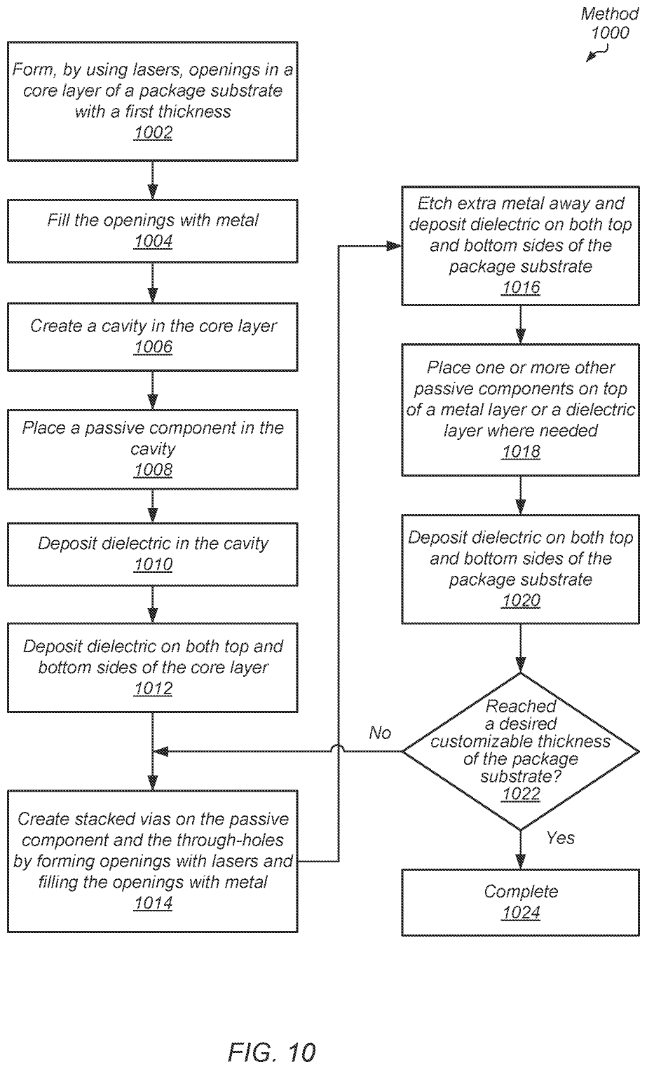

Referring to FIG. 10, a generalized block diagram is shown of a method 1000 for efficiently creating a silicon package substrate with multiple layers of embedded passive components. For purposes of discussion, the steps in this implementation (as well as in FIG. 11) are shown in sequential order. However, in other implementations some steps occur in a different order than shown, some steps are performed concurrently, some steps are combined with other steps, and some steps are absent.

A semiconductor fabrication process (or process) forms, by using lasers, openings in a core layer of a package substrate with a first thickness (block 1002). The process fills the openings with metal (block 1004). The process creates a cavity in the core layer (block 1006). The process places a passive component in the cavity (block 1008). The process deposits dielectric in the cavity (block 1010). The process deposits dielectric on both top and bottom sides of the core layer (block 1012). The process creates stacked vias on the passive component and the through-holes by forming openings with lasers and filling the openings with metal (block 1014).

The process etches extra metal away and deposit dielectric on both top and bottom sides of the package substrate (block 1016). The process places one or more other passive components on top of a metal layer or a dielectric layer where needed (block 1018). The process deposits dielectric on both top and bottom sides of the package substrate (block 1020). If a desired customizable thickness of the package substrate has not yet been reached (“no” branch of the conditional block 1022), then control flow of method 1200 returns to block 1014 where the process creates stacked vias on the passive component and the through-holes by forming openings with lasers and filling the openings with metal. If the desired customizable thickness of the package substrate has been reached (“yes” branch of the conditional block 1022), then the process completes (block 1024). The package substrate is ready to be placed in a chip package.

Referring to FIG. 11, a generalized block diagram is shown of a method 1100 for efficiently creating a chip package with a silicon package substrate that has multiple layers of embedded passive components. A semiconductor fabrication process (or process) forms a package substrate with multiple signal routes using stacked vias from one side of the package substrate to an opposite side of the package substrate (block 1102). The process forms the package substrate with multiple embedded passive components with different thicknesses in different layers of the package substrate (block 1104). In various implementations, the package substrate includes the materials, layers, and the multiple passive components of the package substrates 100-800 (of FIGS. 1-8).

The process places a first side of the package substrate on multiple interconnects of a motherboard (block 1106). The process places an integrated circuit on a second side different from the first side of the package substrate (block 1108). The process completes the connections of the chip package, which can be one of a ball grid array (BGA) surface mount package, a chip scale package (CSP), or a System in Package (SiP). A potential, such as at least one power supply voltage, is applied to one or more nodes of the chip package in addition to components on the motherboard. If the package substrate does not receive data to transfer (“no” branch of the conditional block 1110), then the package substrate waits for data (block 1112). However, if the package substrate receives data to transfer (“yes” branch of the conditional block 1110), then the package substrate conveys the data from a first side of the package substrate that received the data to a second side opposite the first side of the package substrate (block 1114).

Referring to FIG. 12, one implementation of a computing system 1200 is shown that utilizes multiple embedded passive components located in multiple layers of a package substrate. The computing system 1200 utilizes a chip package 1240, which includes the package substrate 1220. The package substrate 1220 has multiple embedded passive components located in multiple layers. In various implementations, the package substrate 1220 includes the materials, layers, and the multiple passive components of the package substrates 100-800 (of FIGS. 1-8). The chip package 1240 uses one of a ball grid array (BGA) surface mount package, a chip scale package (CSP), and a System in Package (SiP). The chip package 1240 communicates with other components on a motherboard (or printed circuit board). In an implementation, the computing system 1200 includes the processor 1210 and the memory 1230 in the chip package 1240.

In another implementation, only one of the processor 1210 and the memory 1230 is included in the chip package 1240. Although a single processor is shown, in other implementations, the chip package 1240 includes another number of processors and a variety of other types of integrated circuits (ICs). The number and type of ICs located in the chip package 1240 is based on design requirements. Interfaces, such as a memory controller, a bus, or a communication fabric, one or more phased locked loops (PLLs) and other clock generation circuitry, a power management unit, and so forth, are not shown for ease of illustration. Additionally, in the illustrated implementation, the chip package 1240 is connected to the disk memory 1254 through the memory bus 1250 and the input/output (I/O) controller and bus 1252.

It is understood that in other implementations, the computing system 1200 includes one or more peripheral devices, a network interface, one or more other memory devices, and so forth. In some implementations, the functionality of the computing system 1200 is incorporated on a system on chip (SoC). In other implementations, the functionality of the computing system 1200 is incorporated on a peripheral card inserted in a motherboard. The computing system 1200 is used in any of a variety of computing devices such as a desktop computer, a server computer, a tablet computer, a laptop, a smartphone, a smartwatch, a gaming console, a personal assistant device, and so forth.

The processor 1210 includes hardware such as circuitry. In various implementations, the processor 1210 includes one or more processing units. In some implementations, each of the processing units includes one or more processor cores capable of general-purpose data processing, and an associated cache memory subsystem. In such an implementation, the processor 1210 is a central processing unit (CPU). In another implementation, the processing cores are compute units, each with a highly parallel data microarchitecture with multiple parallel execution lanes and an associated data storage buffer. In such an implementation, the processor 1210 is a graphics processing unit (GPU), a digital signal processor (DSP), or other.

In some implementations, the memory 1230 includes one of a variety of types of dynamic random access memories (DRAMs). The memory 1230 stores at least a portion of an operating system (OS) 1232, one or more applications represented by code 1234, and at least source data 1236. In various implementations, the memory 1230 stores a copy of these software components 1232, 1234 and 1236 that have original copies stored on disk memory 1254. Memory 1230 is also capable of storing intermediate result data and final result data generated by the processor 1210 when executing a particular application of code 1234.

In various implementations, the off-chip disk memory 1254 includes one or more hard disk drives (HDDs) and Solid-State Disks (SSDs) comprising banks of Flash memory. The I/O controller and bus 1252 supports communication protocols with the off-chip disk memory 1254. Although a single operating system 1232 and a single instance of code 1234 and source data 1236 are shown, in other implementations, another number of these software components are stored in memory 1230 and disk memory 1254. The operating system 1232 includes instructions for initiating the boot up of the processor 1210, assigning tasks to hardware circuitry, managing resources of the computing system 1200 and hosting one or more virtual environments.

It is noted that one or more of the above-described implementations include software. In such implementations, the program instructions that implement the methods and/or mechanisms are conveyed or stored on a computer readable medium. Numerous types of media which are configured to store program instructions are available and include hard disks, floppy disks, CD-ROM, DVD, flash memory, Programmable ROMs (PROM), random access memory (RAM), and various other forms of volatile or non-volatile storage. Generally speaking, a computer accessible storage medium includes any storage media accessible by a computer during use to provide instructions and/or data to the computer. For example, a computer accessible storage medium includes storage media such as magnetic or optical media, e.g., disk (fixed or removable), tape, CD-ROM, or DVD-ROM, CD-R, CD-RW, DVD-R, DVD-RW, or Blu-Ray. Storage media further includes volatile or non-volatile memory media such as RAM (e.g., synchronous dynamic RAM (SDRAM), double data rate (DDR, DDR2, DDR3, etc.) SDRAM, low-power DDR (LPDDR2, etc.) SDRAM, Rambus DRAM (RDRAM), static RAM (SRAM), etc.), ROM, Flash memory, non-volatile memory (e.g., Flash memory) accessible via a peripheral interface such as the Universal Serial Bus (USB) interface, etc. Storage media includes microelectromechanical systems (MEMS), as well as storage media accessible via a communication medium such as a network and/or a wireless link.

Additionally, in various implementations, program instructions include behavioral-level descriptions or register-transfer level (RTL) descriptions of the hardware functionality in a high level programming language such as C, or a design language (HDL) such as Verilog, VHDL, or database format such as GDS II stream format (GDSII). In some cases, the description is read by a synthesis tool, which synthesizes the description to produce a netlist including a list of gates from a synthesis library. The netlist includes a set of gates, which also represent the functionality of the hardware including the system. The netlist is then placed and routed to produce a data set describing geometric shapes to be applied to masks. The masks are then used in various semiconductor fabrication steps to produce a semiconductor circuit or circuits corresponding to the system. Alternatively, the instructions on the computer accessible storage medium are the netlist (with or without the synthesis library) or the data set, as desired. Additionally, the instructions are utilized for purposes of emulation by a hardware based type emulator from such vendors as Cadence®, EVE®, and Mentor Graphics®.

Although the implementations above have been described in considerable detail, numerous variations and modifications will become apparent to those skilled in the art once the above disclosure is fully appreciated. It is intended that the following claims be interpreted to embrace all such variations and modifications.

What is claimed is:

1. An apparatus comprising:
one or more integrated circuits (ICs);
a plurality of interconnects to a motherboard; and
a package substrate configured to transfer data between a given IC of the one or more ICs and the plurality of interconnects through a plurality of signal routes, wherein one or more of the plurality of signal routes comprises stacked vias from one side of the package substrate to an opposite side of the package substrate.

2. The apparatus as recited in claim 1, wherein the package substrate comprises a plurality of embedded passive components with at least two passive components having two different thicknesses.

3. The apparatus as recited in claim 1, wherein the package substrate comprises a plurality of embedded passive components with at least two passive components located in two different layers of the package substrate.

4. The apparatus as recited in claim 1, wherein one or more of the plurality of signal routes comprises an embedded passive component with a first thickness less than a second thickness of a core layer of the package substrate.

5. The apparatus as recited in claim 1, wherein a pitch of the plurality of signal routes is independent of area that can be consumed by passive components between the given IC and the package substrate.

6. The apparatus as recited in claim 5, wherein the pitch is set by a granularity of lasers used during fabrication of the package substrate.

7. The apparatus as recited in claim 1, wherein the plurality of signal routes foregoes use of plated through-holes.

8. A method, comprising:
forming, by a semiconductor fabrication process, a package substrate comprising a plurality of signal routes, wherein one or more of the plurality of signal routes comprises stacked vias from one side of the package substrate to an opposite side of the package substrate;
placing, by the semiconductor fabrication process, a first side of the package substrate on the plurality of interconnects;
placing, by the semiconductor fabrication process, a given integrated circuit (IC) of one or more ICs on a second side different from the first side of the package substrate; and
responsive to receiving data on a given side of the first side and the second side of the package substrate, conveying, by the plurality of signal routes, the data to an opposite side different from the given side of the package substrate.

9. The method as recited in claim 8, further comprising, forming, by the semiconductor fabrication process, a plurality of embedded passive components in the package substrate such that at least two passive components have two different thicknesses.

10. The method as recited in claim 8, further comprising, forming, by the semiconductor fabrication process, a plurality of embedded passive components in the package substrate such that at least two passive components are located in two different layers of the package substrate.

11. The method as recited in claim 8, further comprising, forming, by the semiconductor fabrication process, one or more of the plurality of signal routes with an embedded passive component with a first thickness less than a second thickness of a core layer of the package substrate.

12. The method as recited in claim 9, further comprising, forming, by the semiconductor fabrication process, the plurality of signal routes such that a pitch of the plurality of signal routes is independent of area that can be consumed by passive components between the given IC and the package substrate.

13. The method as recited in claim 12, wherein the pitch is set by a granularity of lasers used during fabrication of the package substrate.

14. The method as recited in claim 8, further comprising, forming, by the semiconductor fabrication process, the plurality of signal routes such that the plurality of signal routes forego use of plated through-holes.

15. A computing system comprising:
a memory configured to store one or more applications of a workload; and
a chip package comprising:
one or more integrated circuits (ICs);
a plurality of interconnects to a motherboard; and
a package substrate configured to transfer data between a given IC of the one or more ICs and the plurality of interconnects through a plurality of signal routes, wherein one or more of the plurality of signal routes comprises stacked vias from one side of the package substrate to an opposite side of the package substrate.

16. The computing system as recited in claim 15, wherein the package substrate comprises a plurality of embedded passive components with at least two passive components having two different thicknesses.

17. The computing system as recited in claim 15, wherein the package substrate comprises a plurality of embedded passive components with at least two passive components located in two different layers of the package substrate.

18. The computing system as recited in claim 15, wherein one or more of the plurality of signal routes comprises an embedded passive component with a first thickness less than a second thickness of a core layer of the package substrate.

19. The computing system as recited in claim 15, wherein a pitch of the plurality of signal routes is independent of area that can be consumed by passive components between the given IC and the package substrate.

20. The computing system as recited in claim 19, wherein the pitch is set by a granularity of lasers used during fabrication of the package substrate.
